(19) United States
(12) Patent Application Publication
(10) Pub. No.: US 2009/0283140 A1
(43) Pub. Date: Nov. 19, 2009

(54) METHOD OF MAKING CONTACT TO A SOLAR CELL EMPLOYING A GROUP IBIIIAVIA COMPOUND ABSORBER LAYER

(76) Inventors: James Freitag, Sunnyvale, CA (US); Mustafa Pinarbasi, Morgan Hill, CA (US); Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/123,424

(22) Filed: May 19, 2008

(51) Int. Cl. H01L 31/00; H01L 31/02

(52) U.S. Cl. 136/256; 438/80; 257/E31.113

(57) ABSTRACT

A solar cell manufacturing method which forms a Group IBIIAVIA absorber layer over a front side of a metallic substrate. The back side of the metallic substrate is coated with a conductive protection layer, such as a metal nitride material, that that does not form a high resistivity selenide or sulfide films when exposed to Se and S species at temperatures in the range of 400-600 C. Additionally, the protection material layer is stable in highly acidic and basic electroplating solutions that are employed to deposit layers or precursor layers comprising Cu and at least one of In, Ga, Se and S.

### BACKGROUND

1. Field of the Invention

The present invention relates to method and apparatus for manufacturing thin film radiation detectors and photovoltaic devices.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications. It should be noted that although the chemical formula for CIGS(S) is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which comprises a material in the family of Cu(In,Ga,Al)(S,Se,Te)₂, is grown over a conductive layer 13 or contact layer, which is previously deposited on the substrate 11 and which acts as the electrical contact to the device. The substrate 11 and the contact layer 13 form a base 20 on which the absorber film 12 is formed, Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 can then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. A terminal structure in the form of a metallic grid typically including busbars and conductive fingers (not shown) is deposited over the transparent layer 14.

Recently, metallic substrate materials, such as a stainless steel or aluminum-based alloy foils, have received considerable attention as potential replacements for the other counterparts such as glass and polymers. The metallic substrates or metallic bases give, for example, the advantage of large area absorber film manufacturing through roll to roll techniques. As mentioned above, when a metallic substrate is used, electrical connection to the solar cell can be advantageously made to the metallic substrate when a group of individual cells are interconnected to form solar modules. In a solar module, each solar cell substrate is electrically interconnected to the terminal of the next solar cell. However, while very promising, depositing Cu(In,Ga)(S,Se)₂ or CIGS(S) absorber films on conductive bases has a significant drawback including the fact that unwanted material is deposited on the exposed back surface of the metallic substrate during the manufacture of absorber layers over the front surface of the substrate.

FIG. 2 exemplifies a solar cell 30 including a conductive substrate 32 with a contact layer 34, a CIGS(S) absorber layer 36 formed on the contact layer and a transparent conductive layer 38 formed on the absorber layer using the conventional techniques. While the absorber layer 36 is formed, a reaction product film 40 or scale forms on the exposed back surface 42 of the conductive substrate 32. CIGS(S) absorber layers are typically grown in a chemical environment comprising volatile or vapor species of at least one of Se and S at elevated temperatures of about 400-600° C. Selenium and S are highly reactive elements and upon reaction with the exposed back surface of the substrate (which may be stainless steel or aluminum-based alloy) they form a scale comprising selenides and/or sulfides of materials present in the chemical composition of the substrate. Such reaction product films, for example, include metal selenides and metal sulfides such as Fe-selenide/sulfide, Al-selenide/sulfide, Cr-selenide/sulfide etc. The bulk resistivity values of such selenides are typically larger than 1 ohm-cm and may go as high as 10⁴ ohm-cm. When a back contact (not shown) is attached to the conductive substrate 32, on top of the reaction product film 40, presence of a resistive selenide and/or sulfide film or scale between the bulk of the substrate and the back contact increases the overall series resistance of the solar cell and reduces its conversion efficiency. The thickness of the selenide/sulfide scale may be between about 50-500 nm, depending on the CIGS growth temperature and the reactivity of the Group VIA vapors present in the growth environment. The selenide/sulfide scale may also cause long term reliability issues because it may react in time with the materials of the contact, such as silver containing pastes and/or epoxies.

Additionally, such scale or film of selenide and/or sulfide materials may be mechanically weak and may break under stress causing contact delamination. Presence of a scale, made of metal selenides and/or sulfides at the back surface of the substrate, may also cause particle generation problem especially since metal selenides and sulfides forming at the back surface of the substrate may not adhere well to the substrate. This problem may be even worse for the case of two-stage processes that employ roll-to-roll reaction of precursor layers deposited on metallic foil substrates in roll-to-roll reactors. In a roll-to-roll reactor there is relative motion between the conductive substrate and the reactor, and the back surface of the substrate may rub against a surface in the roll-to-roll reactor. Therefore, particles may come off the reaction product film and accumulate in the reactor. Once these particles find their way to the CIGS(S) layer on the other side of the substrate, they may cause electrical and mechanical defects in the CIGS(S) layer and lower the efficiency of solar cells that may be fabricated on such defective layers.

Molybdenum layers have previously been used to cover the back side or back surface of flexible polyimide or Kapton™ foil substrates to reduce curling of the thin substrate once a Mo contact layer and a CIGS layer is grown on one face (see for example, U.S. Pat. No. 6,310,281). Although Mo can be used for such stress-balancing purpose on the back surface of a thin foil substrate, it is not a good chemical barrier to selenization and sulfidation. Molybdenum forms a surface film or surface scale of high resistivity Mo-selenide and/or sulfide layer with thicknesses ranging from 100 nm to 500 nm when exposed to Se and/or S vapors at elevated temperatures. Therefore, Mo does not, by itself, resolve the problems described above, especially the problem of particle generation in a roll-to-roll reactor. For two-stage techniques employing electrodeposited precursor layers such as precursor layers comprising electroplated Cu, In, Ga and at least one of Se and S, use of Mo as a barrier layer on the back surface of the metallic substrate presents additional problems. Molybdenum does not have a stable surface oxide layer and therefore is not stable in plating electrolytes employed for electroplating comprising Cu, In, Ga, Se etc. During electroplating, the surface of Mo wetted by the electroplating solution may leach into the solution eventually rendering it unsuitable for process.

From the foregoing, there is a need to develop a conductive substrate structure that does not produce a high resistivity film or scale on its back surface when exposed to a CIGS(S) film growth atmosphere. Furthermore there is also need for a conductive substrate structure that is stable and does not dissolve in electrolytes with pH values ranging from acidic (greater than 7) to basic (less than 7).

### SUMMARY OF THE INVENTION

The present invention provides for a method and apparatus for manufacturing thin film radiation detectors and photovoltaic devices.

In one aspect is described a method of forming a solar cell using a metallic substrate having a back surface and a front surface and allowing a low resistivity ohmic contact to be made thereto when connecting one solar cell to a terminal of another solar cell. The method comprises:

depositing a contact layer on the front surface of the metallic substrate; depositing an electrically conductive protection layer on the back surface onto which the low resistivity ohmic contact can be made to electrically connect the electrically conductive protection layer of the one solar cell to the terminal of the another solar cell, wherein the electrically conductive protection layer includes one of a metal nitride material, Ru, Ir and Os; and forming a Cu(In,Ga)(S,Se,Te)2 absorber layer over the contact layer.

In another aspect there is provided a solar cell, comprising:

a conductive substrate having a back surface and a front surface; a contact layer deposited over the front surface; an electrically conductive protection layer deposited on the back surface, the electrically conductive protection layer including one of a metal nitride material, Ru, Ir and Os; and a Group IBIIIAVIA absorber layer formed over the contact layer.

These and other aspects and advantages of the present invention are described hereafter.

### BRIEF DESCRIPTION OF THE DRAWINGS

FIG. 1 is a schematic view of a solar cell employing a Group IBIIIAVIA absorber layer;

FIG. 2 is a schematic view of a solar cell employing a Group IBIIIAVIA absorber layer, wherein there is a reaction product film formed on a back surface of a metallic substrate;

FIG. 3 is a schematic view of a solar cell base structure of the present invention having a protection layer coating a back side of a metallic substrate;

FIG. 4 is a schematic view of a solar cell using the base structure of the present invention shown in FIG. 3; and

FIG. 5 is a schematic view of a solar cell string having two solar cells using the base structure of the present invention, wherein a conductive lead electrically connects the protection layer of the first cell to a terminal of the second solar cell.

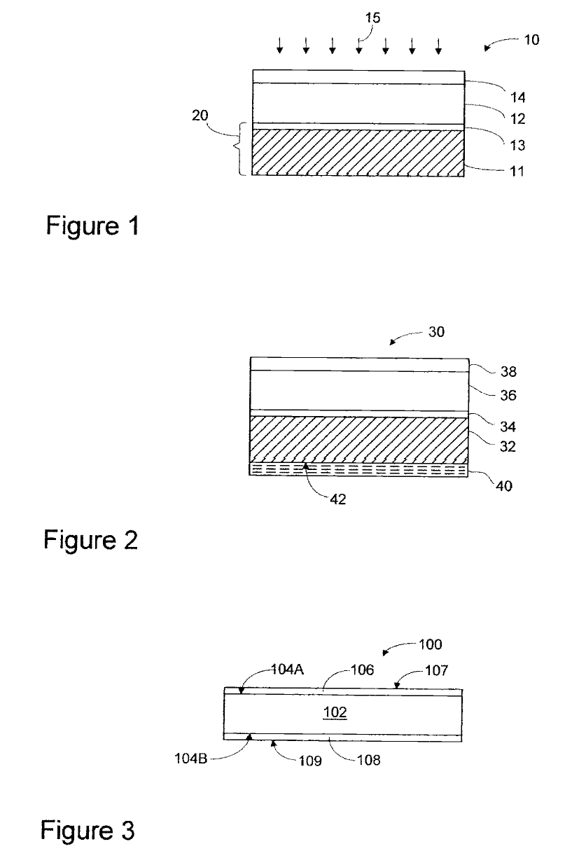

### DETAILED DESCRIPTION OF THE INVENTION

Present invention overcomes the shortcomings of prior art techniques by coating the back side of a metallic substrate with a protection material layer that does not form a high resistivity selenide and/or sulfide film when exposed to Se and/or S species at temperatures in the range of 400-600 C. Furthermore the protection material layer is stable in highly acidic and basic electroplating solutions that may be employed to deposit layers or precursor layers comprising Cu and at least one of In, Ga, Se and S.

FIG. 3 illustrates an embodiment of a solar cell base 100 or back side of a solar cell which is formed in accordance with the principles of the present invention to manufacture a Group IBIIIAVIA solar cell. The base 100 of the present invention is preferably a conductive substrate 102 having a front surface 104A and a back surface 104B. The conductive substrate 102 may be a stainless steel, aluminum or another conductive substrate. In this embodiment, the conductive substrate 102 is preferably a stainless steel substrate. A contact layer 106 having a surface 107 is formed the front surface 104A of the conductive substrate 102. The contact layer may be at least one of the commonly used materials for making ohmic contact to CIGS layers. These materials comprise at least one of Mo, Ta, W, Ti, and their nitrides. They may also comprise at least one of Ru, Ir, and Os, which have been developed as ohmic contacts to CIGS type solar cells by the assignee of this patent application. The back surface 104B of the substrate 102 is coated with an electrically conductive protection layer 108 (also referred to as just “protection layer 108”), having a surface 109, of the present invention. As will be described below, no appreciable scale or unwanted film forms on the surface 109 of the protection layer 108 during the following process steps.

The protection layer 108 is selected from a group of materials that are not chemically affected from the electroplating process environment of Cu, In, Ga and Se species. In other words, the protection layer is chemically stable in liquid chemical environment with pH values ranging from 0 to about 14. In addition, the protection layer is stable during the selenization and sulfurization process steps and has good adhesion to the substrate material at high processing temperatures applied during the processes. In other words the protection layer is chemically stable in vapor phase reactants of Group VIA materials like Se, Te and S. Additionally, the protection layer has metallic character with low resistivity so that low resistance ohmic contacts may be formed on it, thus making the protection layer a good electrical conductor. The bulk resistivity of the protection layer may be less than about 0.1 ohm-cm, preferably less than about 0.01 ohm-cm, and most preferably less than about 0.001 ohm-cm. In one embodiment, the protection layer may be a metal nitride including but not limited to tungsten-nitride (WN),TaN, MoN, TiN, HfN, and ZrN. The nitrogen-to-metal molar ratio in such nitrides may be preferably 1, but it may also be more or less than one. In any case the preferred composition of the nitride has at least 10% nitrogen in the metal.

Alternately, the protection layer 108 may comprise at least one of Ru, Ir and Os. These are special elements with chemical resistance to liquid reactants as well as to vapors of Group VIA elements.

The protection layer 108 may be sputter deposited on the back surface 104B of the substrate. The thickness of the protection layer 108 may be in the range of 5-500 nm, preferably in the range of 20-200 nm, most preferably in the range of 50-100 nm. In another embodiment, the protection layer 108 may be a stack (not shown) having multiple sub-layers or layers, such as two layers. A first layer of this stack may be formed on the surface 109 of the substrate and may comprise a material that provides good adhesion to the surface 109. Such materials include but are not limited to Cr, Mo, W, Ta, Ti, etc. A second layer deposited on the first layer may comprise at least one of a metal nitride (such as WN, MoN, TaN, TiN, HfN, ZrN, and other metal nitrides), Ru, Ir and Os. It should be noted that the surface 109 of the protection layer is a material that is resistive to acidic and basic pH solutions (i.e. does not chemically dissolve in such liquids in any appreciable manner) and at the same time resists reaction with Se and/or S at temperatures as high as 600° C. For example, the chemical dissolution of such materials in solutions with pH values in the 0-14 range may be in the range of 0-1 nm/min and when reacted with Se and/or S, the scale of selenide or sulfide formed on their surface may have a thickness in the range of 0-5 nm after 10-20 minute reaction at a temperature in the range of 400-600° C.

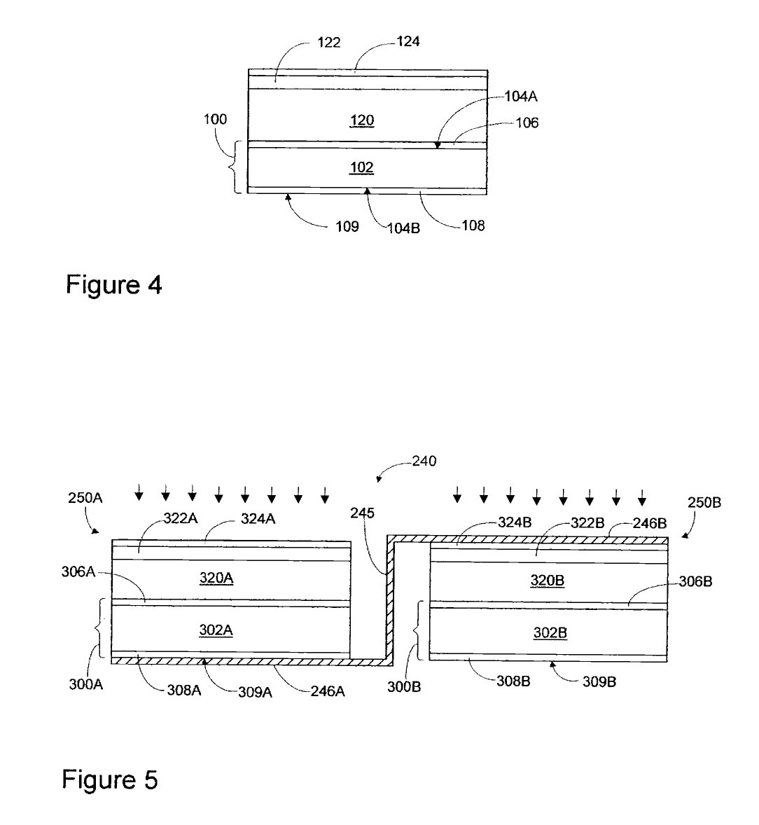

As shown in FIG. 4, once one of the bases described above, for example the base 100 shown in FIG. 3, is prepared, a Group IBIIIAVIA absorber layer 120 is formed on the base 100. The absorber layer may be formed over the contact layer 106 by first depositing a precursor film comprising Cu, In, Ga, and at least one of Se and S layers. Such precursor films may be deposited by various techniques such as evaporation, sputtering, electrodeposition, ink deposition, etc, and they may be in the form of a mixture, an alloy or two or more sub-layers deposited one after another in a sequential manner on the contact layer 106. In the preferred embodiment the precursor film is deposited out of liquid solutions or electrolytes using an electroplating or electrodeposition process. Examples of precursor films include but are not limited to Cu—In—Ga—Se alloy or mixture layers and stacks with structures such as Cu/Ga/In, Cu/In/Ga, Cu/Ga/Cu/In, Cu/In/Ga/Se, Cu/Ga/In/Sc, Cu/Ga/Cu/In/Se, and the like. The stacks may preferably be formed by electroplating some or all of the sub-layers of Cu, In, Ga and Se and/or Te. Since the back surface of the substrate is covered with a chemically inert protection layer, the back surface is protected from the electrodeposition solutions. Furthermore, chemical dissolution of the conductive substrate 102 into the electroplating solutions is prevented by the protection layer and thus contamination of the plating solutions is avoided. Such contamination would render the plating solutions unstable and eventually ineffective, especially in a roll-to-roll process where continuous plating on a 5000-10000 ft long substrate may be carried out for periods of days at a time. If the contamination level of the plating bath increases with time (due to continuous dissolution of the substrate back surface into the solution) the electroplating efficiency and the impurity content in the electroplated precursor film would be varying along the length of the roll substrate, early plated parts being pure but the impurity level continuously increasing towards the end of the 5000-10000 ft long precursor film. This would cause variation in the efficiency of solar cells fabricated using such precursor layers and thus reduce the yield of the process.

The precursor deposition process step is followed by an annealing or reaction step at 400-600° C., where excess Group VIA material vapors comprising Se and/or S or Te may be provided to the precursor film, to convert it into a CIGS(S) absorber layer. During this annealing stage of the process, Cu, In and Ga react with the Group VIA material(s) and form the CIGS(S) layer on the contact layer. Since the back surface of the substrate is covered with a chemically inert protection layer, a roll-to-roll process may be utilized for this reaction step without particle generation and accumulation problems described before. After completing the process of forming the absorber layer 120, the surface 109 does not contain any substantial amount of high resistivity selenides and/or sulfides. Any reacted surface scale may be thinner than about 100 nm, typically thinner than 50 nm. In the following solar cell manufacturing steps, a transparent layer 122 is deposited on the absorber layer 120, and a terminal 124 having a busbar and finger pattern (not shown) is formed on the transparent layer. The transparent layer 122 may comprise a buffer-layer/TCO stack formed on the absorber layer, where TCO stands for transparent conductive oxide. An exemplary buffer layer may be a (Cd,Zn)S layer. An exemplary TCO layer may be a ZnO layer, an indium tin oxide (ITO) layer or a stack comprising both ZnO and ITO.

FIG. 5 shows a portion of a solar cell string of a module 240 structure having a first solar cell 250A and a second solar cell 250B may be formed using the process of the present invention. In the module 240, the first solar cell 250A is electrically interconnected to the second solar cell 250B by a conductive lead 245. The conductive lead 245 may be a strip of metal, preferably a conductive ribbon made of copper or any another conductor.

The first solar cell includes a back side including a base 300A having a substrate 302A, a contact layer 306A and a protection layer 308A with a surface 309A. A front side of the first solar cell 250A includes an absorber layer 320A formed on the base 300A, a transparent conductive layer 322A and a terminal 324A on top of the solar cell. Similarly, the second solar cell 250B includes a back side including a base 300B having a substrate 302B, a contact layer 306B and a protection layer 308B with a surface 309B. A front side of the second solar cell 250B includes an absorber layer 320B formed on the base 300B, a transparent conductive layer 322B and a terminal 324B on top of the solar cell. Arrows depict the direction of the incoming light. During the interconnection process, a first end 246A of the conductive lead 245 is attached to surface 309A of the protective layer 308A and a second end 246B is attached to the terminal 324B of the second solar cell 250B. A bonding material may be used to attach the conductive lead to the solar cell. The bonding material may be a conductive adhesive such as Ag-filled adhesive, solder material or the like.

Since there is no high resistivity reaction product at the interface between the first end 246A (bottom electrical contact) of the conductive lead and the protection layer 308A, series resistance introduced by this electrical contact is minimized. It should be noted that although it is preferable to cover the entire area of the surface 309A with the protection layer 308A of the present invention, the protection layer may only be applied to selective sections on the surface 309A corresponding to areas where the first end 246 A or the bottom contact will be applied. This way low resistance contacts may still be obtained. However, such partial application of the protection layer on the back surface of the substrate does not address the chemical dissolution problem if electrodeposition is used for the deposition of precursor films.

Although the present invention is described with respect to certain preferred embodiments, modifications thereto will be apparent to those skilled in the art.

We claim:

1. A method of forming a solar cell using a metallic substrate having a back surface and a front surface and allowing a low resistivity ohmic contact to be made thereto when connecting one solar cell to a terminal of an other solar cell, the method comprising:
depositing a contact layer on the front surface of the metallic substrate; depositing an electrically conductive protection layer on the back surface onto which the low resistivity ohmic contact can be made to electrically connect the electrically conductive protection layer of the one solar cell to the terminal of the other solar cell, wherein the electrically conductive protection layer includes one of a metal nitride material, Ru, Ir and Os; and forming a Cu(In,Ga)(S,Se,Te)2 absorber layer over the contact layer.

2. The method of claim 1, wherein the metal nitride material comprises one of WN, TaN, MoN, TiN, HfN and ZrN.

3. The method of claim 2, wherein forming the Cu(In,Ga)(S,Se,Te)₂ absorber layer comprises:
forming a precursor layer comprising Cu and at least two of In, Ga, Se, Te and S over the contact layer; and
heating the precursor layer in an environment comprising at least one of Se, Te and S.

4. The method of claim 3, wherein the step of forming the precursor layer is carried out by electroplating.

5. The method according to claim 3, wherein heating is carried out at a temperature range of 400-600° C.

6. The method of claim 1 further comprising the step of depositing an adhesion layer onto the back surface of the metallic substrate before depositing the electrically conductive protection layer, wherein the adhesion layer comprises one of Cr, Mo, W, Ta and Ti.

7. The method of claim 1 further comprising depositing a transparent conductive layer onto the Cu(In,Ga)(S,Se,Te)₂ absorber layer.

8. The method of claim 7, wherein the conductive substrate comprises stainless steel.

9. The method of claim 1, wherein depositing an electrically conductive protection layer deposits the electrically conductive protection layer to a thickness in the range of 5-100 nm.

10. A solar cell, comprising:
a conductive substrate having a back surface and a front surface;
a contact layer deposited over the front surface;
an electrically conductive protection layer deposited on the back surface, the electrically conductive protection layer including one of a metal nitride material, Ru, Ir and Os; and
a Group IBIIIAVIA absorber layer formed over the contact layer.

11. The solar cell of claim 10, wherein the metal nitride material comprises one of WN, TaN, MoN, TiN, HfN and ZrN.

12. The solar cell of claim 11 further comprising an adhesion layer interposed between the metallic substrate and the protection layer, wherein the adhesion layer comprises one of Cr, Mo, W, Ta and Ti.

13. The solar cell of claim 12, wherein the conductive substrate comprises stainless steel.

14. The solar cell of claim 10 further comprising an adhesion layer interposed between the metallic substrate and the protection layer, wherein the adhesion layer comprises one of Cr, Mo, W, Ta and Ti.

15. The solar cell of claim 10, wherein the conductive substrate comprises stainless steel.

16. The solar cell of claim 10, wherein a conductive lead is attached to the electrically conductive protection layer.

17. The solar cell of claim 10 further a transparent conductive layer deposited onto the Group IBIIIAVIA absorber layer.

18. The solar cell of claim 10, wherein the thickness of the electrically conductive protection layer is in the range of 5-100 nm.
